(19) United States
(12) Patent Application Publication
(10) Pub. No.: US 2026/0112866 A1
(43) Pub. Date: Apr. 23, 2026

(54) Distribution assembly and associated electrical panel

(71) Applicant: Schneider Electric Industries SAS, Rueil Malmaison (FR)

(72) Inventors: Eric DOMEJEAN, Voreppe (FR); Claude Burnot, Echirolles (FR); Christophe Kilindjian, Saint Nazarie-les-Eymes (FR)

(21) Appl. No.: 19/361,923

(22) Filed: Oct. 17, 2025

(30) Foreign Application Priority Data
Oct. 21, 2024 (FR) FR2411464

(51) Int. Cl. H02B 1/56; H02B 1/01; H02B 1/21; H05K 7/20

(52) U.S. Cl. CPC H02B 1/56; H02B 1/012; H02B 1/21; H05K 7/20127

(57) ABSTRACT

This distribution assembly (100), configured to distribute electrical energy from a power source to at least one electrical load, comprises a power bus (124) which comprises a plurality of busbars (122) each having, at one end, a portion for connection to an output terminal of a main box (200). The power bus defines a connection zone, which extends along a connection plane (P124) and is provided for the connection of at least one outgoing box (300) on a front side of the connection plane (P124). The distribution assembly (100) comprises a cooling device (400), which includes a contact plate (410) for cooperation with a rear face (231) of the main housing (200), a radiator (420) which extends from a rear side of the connection plane (P124), and at least one heat pipe (430), which connects the contact plate (410) to the radiator (420).

### BACKGROUND

The present invention relates to an electrical power distribution assembly, and to an electrical panel comprising such a distribution assembly.

The distribution assembly under consideration here makes it possible to connect an electrical power source to at least one electrical load. Distribution devices are known comprising so-called “static” switching means, that is in particular semiconductor switching means, which allow fast, arcless switching. These static switching means are however relatively costly.

It is known practice, in particular from GB 2 182 812 A, to connect static switching means to a plurality of outgoing terminal blocks, each outgoing terminal block respectively being associated with mechanical switching means.

However, static switching means tend to generate significant heat, in particular when their switching function is implemented, which can hinder the satisfactory operation of the distribution assembly, in particular when they are switched several times in close succession. It is known practice to promote heat exchanges by means of ventilation, or even air conditioning, but these solutions are noisy, energy-consuming and unreliable.

### SUMMARY

The invention aims more particularly to overcome these problems, by proposing a distribution assembly that provides improved cooling while remaining relatively compact.

To this end, the invention relates to a distribution assembly, configured to distribute electrical energy from a power source to at least one electrical load, the power source comprising a neutral and at least one phase, wherein:
the distribution assembly comprises a power bus, which includes a plurality of busbars:
   which include at least one phase bar and optionally a neutral bar, the optional neutral bar being associated with the neutral of the power source, each phase bar being associated respectively with a phase of the power source,
   which extend parallel to each other along a main axis of the distribution assembly and are aligned along a height axis that is orthogonal to the main axis,
the busbars each comprise:
   a power supply portion, which is configured to be connected to an output terminal of a main housing in a mounted configuration of the main housing,
   a connection portion, which extends from a single side of the power supply portion, the connection portions being geometrically situated on a front side of a connection plane parallel to the main axis and to the height axis and together defining a connection zone of the power bus, the connection zone being configured to receive at least one outgoing box so that the outgoing box is connected to the power bus, each outgoing box being capable of being connected to an electrical load, so as to supply electrical power to the electrical load,
the distribution assembly comprises a cooling device, which includes:
   a contact plate, which has a contact face that extends parallel to the connection plane, the contact face being configured to cooperate, in particular through complementary shapes, with a rear face of the main housing in a mounted configuration, so as to promote thermal transfer between the contact plate and the main housing,
   a radiator that extends along the connection zone, on a rear side of the connection plane,
   at least one heat pipe, which connects the contact plate to the radiator and is configured to transfer some of the heat collected by the contact plate to the radiator, the radiator being configured to dissipate the heat transferred by each heat pipe into the air.

By virtue of the invention, the space situated on the front of the power bus is intended for the connection of other apparatus, for example protective devices such as outgoing boxes, while the space situated on the rear of the power bus is essentially set aside for the radiator, which makes it possible to efficiently discharge some of the heat generated by the main housing during operation. In addition, the cooling device is passive, that is, it does not consume energy in order to operate, as well as being silent. The cooling device does not comprise a motor or any moving parts, reducing the possibility of failure, which contributes to the reliability of the cooling device and, by extension, of the distribution assembly. The arrangement of the distribution assembly is particularly compact, while providing improved cooling capacity.

According to advantageous, but not obligatory, aspects of the invention, such a distribution assembly can incorporate one or more of the following features taken individually or in any technically acceptable combination:
The distribution assembly includes the main housing, the main housing being mounted on the rest of the distribution assembly and comprising:
   input terminals, which are configured to be connected to each phase and to the optional neutral of the power source,
   output terminals, which are connected to the busbars, each output terminal being associated with a respective busbar and a respective input terminal,
   the rear face, which cooperates, in particular through complementary shapes, with the contact face.
The main housing comprises switching means, in particular static, which can be switched between an on configuration, in which each input terminal is electrically connected to the associated output terminal, the main housing being in an on configuration, and an off configuration, in which an electrical current is prevented from passing between the input terminal and the associated output terminal, the main housing being in an off configuration, while the main housing comprises a rear wall, which is made from a thermally conductive and electrically insulating material and comprises the rear face, the rear wall being interposed between the switching means and the contact plate, so that some of the heat generated by the switching means during operation is transferred to the contact plate through the rear wall.
The at least one heat pipe is a two-phase heat pipe.
The at least one heat pipe is a capillary two-phase heat pipe, while when the distribution assembly is in a normal operating configuration, the main axis is horizontal.
The distribution assembly comprises an insulating wall, which is made from an electrically insulating material and is interposed between the power bus and the radiator, the insulating wall being open towards the front of the contact plate, while the output terminals of the main housing are connecting clips, which are each suitable for connection to a respective busbar, in a connection movement oriented towards the rear of the distribution assembly so that, during the movement to connect the output terminals to the busbars, the rear face of the main housing bears against the contact face.
The distribution assembly comprises a rear portion, which forms a cavity for receiving the cooling device, the rear portion being made from an electrically insulating material,
while the rear portion is perforated, so as to promote the cooling of the cooling device by convection.

The invention also relates to an electrical panel, comprising:
a case, defining an enclosure and having a base,
the distribution assembly as defined above,
   wherein the distribution assembly is fastened to the base of the case, the main axis being parallel to the base of the case, preferably horizontal.

### BRIEF DESCRIPTION OF DRAWINGS

The invention will be better understood, and further advantages thereof will become more clearly apparent on reading the following description of one embodiment of a distribution assembly and an electrical panel according to the principle thereof, given solely by way of example and with reference to the appended drawings, in which:

FIG. 1 is a partially exploded perspective view of an electrical panel according to the invention, the electrical panel comprising a distribution assembly, also according to the invention;

FIG. 2 is a partially exploded perspective view of the distribution assembly in FIG. 1;

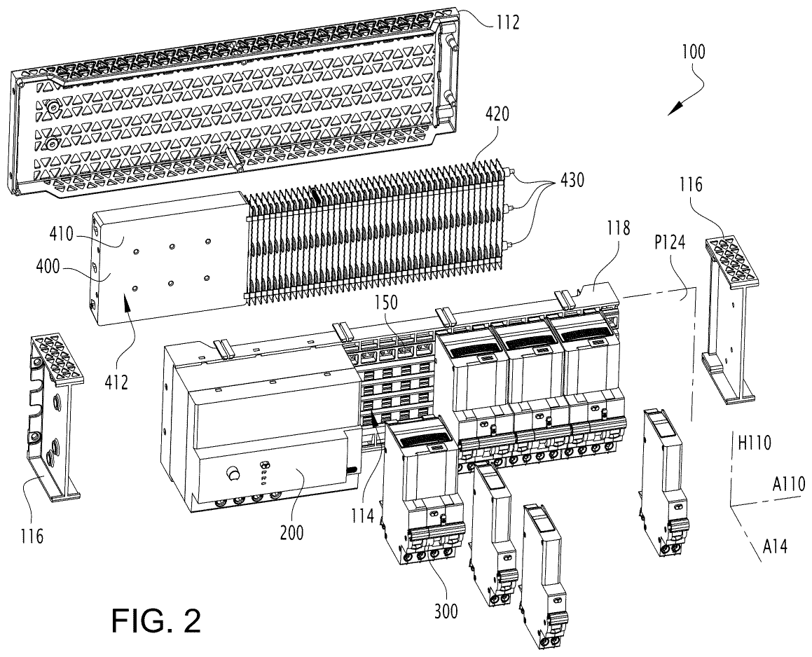

FIG. 3 respectively shows, in two inserts a) and b), a perspective view of the distribution assembly in FIG. 1, in which some parts are concealed, and a perspective view of a transfer bus of the distribution assembly;

FIG. 4 is a partially exploded perspective view of the distribution assembly in FIG. 1, in which some parts are concealed; and

FIG. 5 is a schematic depiction of the distribution assembly in FIG. 1.

### DETAILED DESCRIPTION

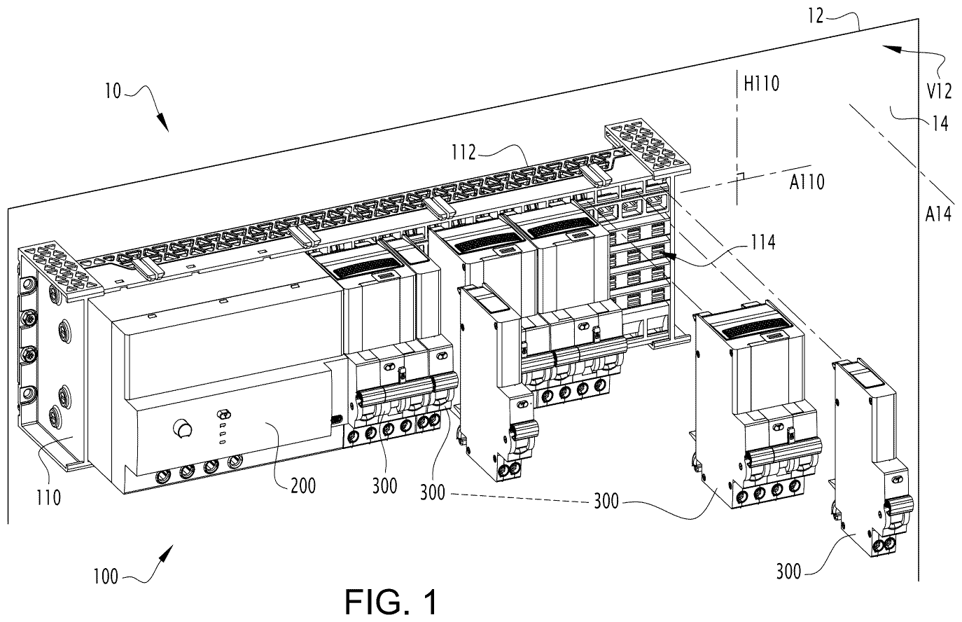

An electrical panel 10, according to the invention, is shown in FIG. 1. The electrical panel 10 comprises a case 12, which defines an enclosure V12 and has a base 14. The base 14 extends generally in a plane orthogonal to a depth axis A14. The enclosure V12 is advantageously closed by a door, not shown.

The electrical panel 10 comprises a distribution assembly 100. The distribution assembly 100 is fastened to the base 14 of the case 12. The distribution assembly 100 is configured to distribute electrical energy from a power source to at least one electrical load, the power source comprising a neutral and at least one phase. The power source and the electrical load, not shown, do not form part of the invention but serve to explain the operating context thereof.

The distribution assembly 100 comprises a distribution device 110, by which the distribution assembly 100 is fastened to the base 14, a main housing 200, which is assembled with the distribution device 110, preferably reversibly, and at least one outgoing box 300, here seven outgoing boxes, each outgoing box 300 being reversibly assembled with the distribution device 110, in a mounted position of the outgoing box 300. It is thus possible to replace, as necessary, the main housing 200 in the event that the main housing 200 malfunctions, while retaining the other elements of the distribution assembly 100, distribution device 110 and outgoing box or boxes 300, which is economical. Likewise, it is possible to replace, as necessary, one or more of the outgoing boxes 300, for example in the event of a malfunction, while retaining the other elements, distribution device 110 and main housing 200, which is economical.

The distribution device 110 has an elongate shape, which extends along a main axis A110. When the distribution assembly 100 is in a normal operating configuration, the main axis A110 is parallel to the base 14, in other words orthogonal to the depth axis A14. Preferably, the main axis A110 is horizontal, as illustrated in FIG. 1. A height axis H110 is defined as being an axis orthogonal to both the depth axis A14 and the main axis A110. The description is given with respect to the orientation of the various elements as shown in the figures, it being understood that this may be different in reality.

In the example in FIG. 1, the main housing 200 is situated on the left of the distribution assembly 100, the outgoing boxes 300 being situated on the right of the main housing 200.

When the distribution assembly 100 is fastened to the base 14, a rear portion 112 of the distribution device 110 is oriented facing the base 14, in other words oriented towards a rear direction of the distribution assembly 100. The rear direction is thus parallel to the depth axis A14. A front direction is also defined as being an opposite direction to the rear direction.

The distribution device 110 thus has a mounting face 114, which is generally oriented towards the front and is suitable for mounting the main housing 200 and each outgoing box 300.

The rear portion 112 is made from an electrically insulating material, for example a synthetic polymer. Here, the rear portion 112 has a generally rectangular shape, which extends along its longest dimension parallel to the main axis A110. The short sides of the rectangle are thus parallel to the height axis H110. Here, the distribution device 110 comprises two flanges 116, which are made from an electrically insulating material. The two flanges 116 are assembled with the short sides of the rear portion 112 so as to form a basket.

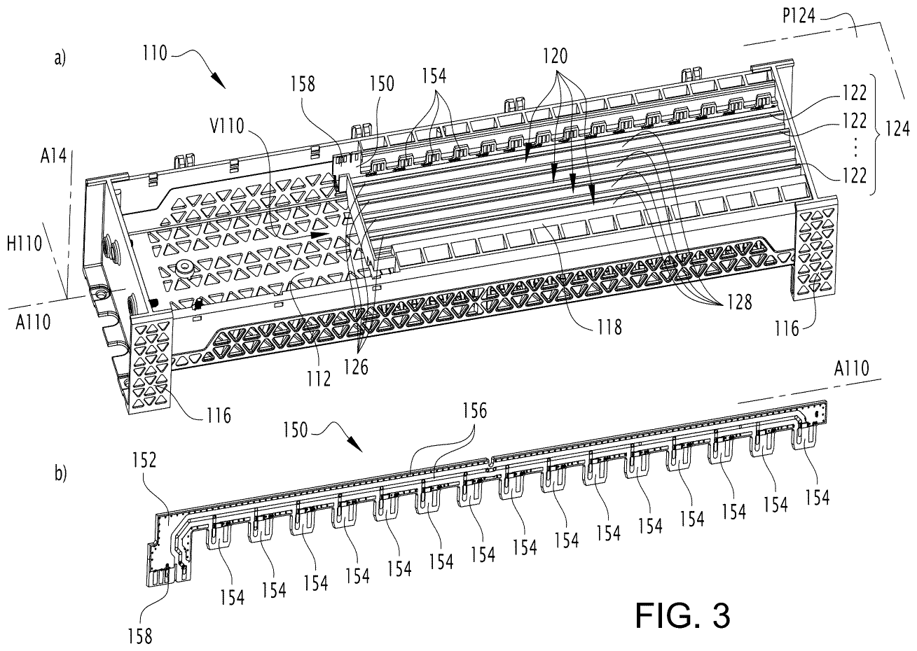

Here, the distribution device 110 comprises an insulating wall 118, which is made from an electrically insulating material and is assembled with the rear portion 112 and the flanges 116, so as to form a cavity V110, as illustrated in FIG. 3.

According to one aspect of the invention, the distribution device 110 comprises a cooling device 400, which is received in the cavity V110 and is suitable for discharging some of the heat generated by the main housing 200 when the distribution assembly 100 is operating. The cooling device 400 is thus situated on a rear side of the insulating wall 118, while on a front side of the insulating wall 118, the front side being oriented in the opposite direction to the rear side, the insulating wall 118 forms grooves 120 suitable for receiving a plurality of busbars 122. The busbars 122 together form a power bus 124 of the distribution device 110 and, by extension, of the distribution assembly 100. The rear portion 112 is preferably perforated, so as to promote the cooling of the cooling device 400 by convection. The distribution device 110 thus forms a cage around the cooling device 400.

The busbars 122 include at least one phase bar and optionally a neutral bar, the neutral bar being associated with the neutral of the power source, each phase bar being associated with a respective phase of the power source. In the example illustrated, the power bus 124 comprises four busbars 122, the power source being a three-phase source with a neutral. Here, the distribution assembly 100 has a so-called “3P+N”, or simply 3PN, configuration.

As a variant, not shown, the power source is three-phase, with or without neutral, while the distribution assembly does not comprise a busbar associated with the neutral. In other words, the distribution assembly only comprises three phase bars, each associated with a respective phase of the power source. The distribution assembly thus has a so-called 3P configuration.

The principles of the invention can be transposed regardless of the number of phases of the power source. According to another variant, not shown, the power source is single-phase, that is, it only comprises the neutral and just one phase. The busbars then include just one phase bar, and the neutral bar. The distribution assembly then has a so-called P+N, or simply PN, configuration. Regardless of the configuration, there is always a plurality of busbars, which include at least one phase bar, and optionally a neutral bar.

The busbars 122 extend parallel to each other along the main axis A110 of the distribution assembly 100 and are aligned along the height axis H100. The busbars 122 together define a connection plane P124, which is a plane orthogonal to the depth axis A14, in other words parallel to the height axis H110 and the main axis A110. The mounting face 114 is generally parallel to the connection plane P124.

The cooling device 400 comprises a contact plate 410, which is suitable for collecting some of the heat released by the main housing 200, a radiator 420, which is suitable for dissipating heat into the ambient air, and at least one heat pipe 430, here three heat pipes, which connects the contact plate 410 to the radiator 420 and is configured to transfer some of the heat collected by the contact plate 410 to the radiator 420.

Here, the contact plate 410 has a parallelepipedal shape and has a contact face 412, which extends parallel to the connection plane P124. The contact face 412 is configured to cooperate, in particular by complementary shapes, with a rear face 230 of the main housing 200 in a mounted configuration on the distribution device 110, so as to promote thermal transfer between the contact plate 410 and the main housing 200.

Here, the radiator 420 is formed by an assembly of metal fins, which are positioned so that they do not hinder the passage of the air. Here, the metal fins are positioned parallel to each other and are aligned along the main axis A110. The heat pipes 430 connect the fins to the contact plate 410.

In general, a heat pipe is a device for transporting heat due to the principle of thermal transfer, for example by thermal conduction, or by convection of a fluid, or by phase transition of a fluid. According to examples, the heat pipes 430 are metal rods, for example copper rods. Preferably, the heat pipes 430 are two-phase heat pipes. In the example illustrated, the heat pipes 430 are capillary two-phase heat pipes. Generally, a capillary two-phase heat pipe comprises two coaxial pipes, which are arranged so as to promote within them the circulation of a heat-transfer fluid that changes phase, between liquid and gas, depending on its temperature. Preferably, the capillary two-phase heat pipes 430 are straight and are arranged horizontally when the distribution assembly 100 is in a normal operating configuration. In other words, the main axis A110 is preferably horizontal. As a variant, not shown, the two-phase heat pipes 430 are “gravity” heat pipes, which are preferably arranged vertically. In other words, in this case the main axis A110 is preferably vertical.

The radiator 420 thus extends along the connection zone of the power bus 124, on a rear side of the connection plane P124. In particular, the radiator 420 is situated on the rear side of the insulating wall 118, the radiator 420 being received in the cavity V110, while the insulating wall 118 is open towards the front of the contact plate 410. In other words, the insulating wall 118 is interposed between the power bus 124 and the radiator 420. The portion of the insulating wall 118 that serves as a support for the busbars 122 is preferably continuous, so as to reduce the risks of electrical arcs between the busbars 122 and the radiator 420.

The busbars 122 include a neutral bar and at least one phase bar, the neutral bar being associated with the neutral of the power source, each phase bar being associated with a respective phase of the power source. In the example illustrated, the power bus 124 comprises four busbars 122, the power source being a three-phase source. The principles of the invention can be transposed regardless of the number of phases of the power source, particularly if the power source is single-phase, that is, only comprises the neutral and just one phase.

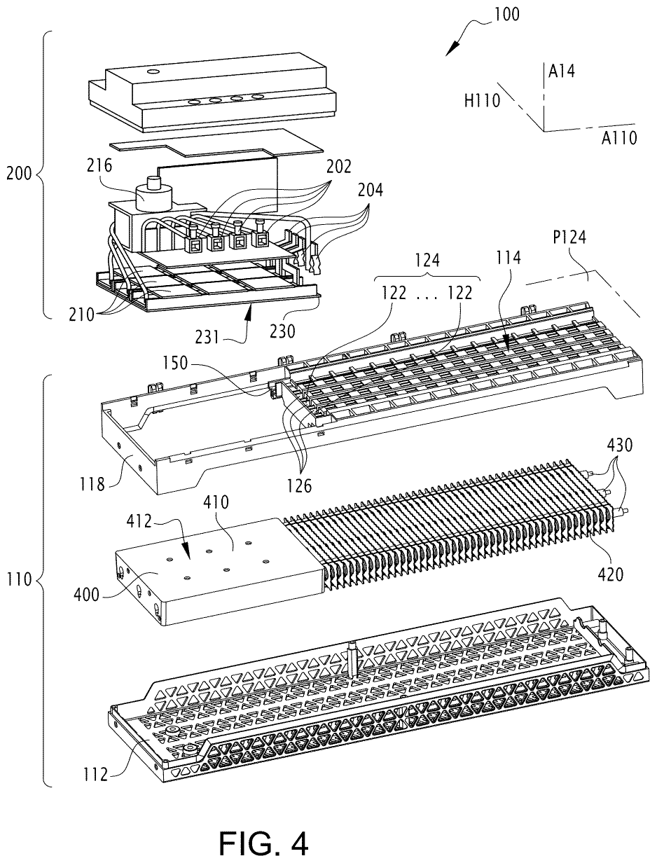

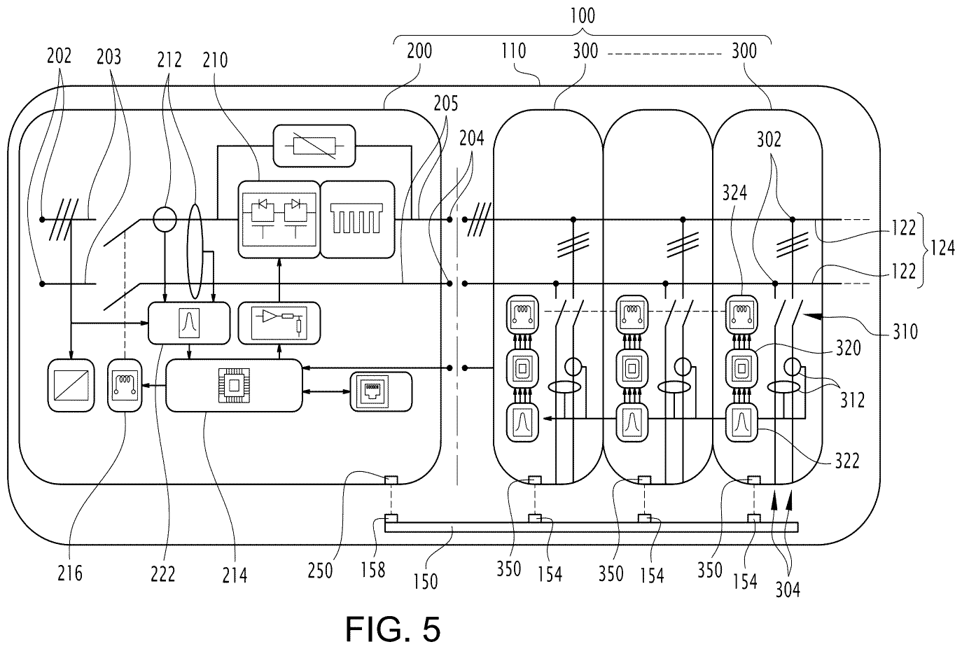

The main housing 200 will now be described, with particular reference to FIGS. 4 and 5. In FIG. 5, the circuit of just one phase is shown, and the three phases are shown, according to known convention, by three parallel lines across the circuit.

The main housing 200 comprises input terminals 202, which are configured to be connected to the neutral and to each phase of the power source, and output terminals 204, which are configured to be connected to the busbars, each output terminal being associated with a respective busbar and with a respective input terminal. Here, the input terminals 202 are screw terminals. Advantageously, the output terminals 204 are connecting clips, which are each suitable for reversible connection to a respective busbar 122, in a connection movement oriented towards the rear of the distribution assembly 100. Thus, during the movement to connect the output terminals 204 to the busbars 122, the rear face of the main housing 200 bears against the contact face 412.

For each input terminal 202, the main housing comprises a corresponding input line 203, which is connected to the corresponding input terminal 202, and an output line 205, which is connected to the associated output terminal 204.

The main housing 200 comprises static switching means 210, which can be switched between an on configuration, in which each input terminal 202 associated with a phase of the power source is electrically connected to the associated output terminal 204, the main housing 200 being in an on configuration, and an off configuration, in which an electrical current is prevented from passing between the input terminal 202 and the associated output terminal 204, the main housing 200 being in an off configuration.

The static switching means 210 are semiconductor component-based power switches, preferably gate field effect transistors, or MOSFETs, and are thus referred to as “static” as opposed to switching means with moving contacts. The static switching means 210 are connected in series between the input line 203 and the associated output line 205. The static switching means 210 are shown schematically in FIGS. 4 and 5.

During operation, the switching means 210 release heat, of the order of a few tens of watts each. The switching means 210 are advantageously positioned so as to promote the transfer of at least some of the heat released to the cooling device 400.

In particular, the switching means 210 are advantageously arranged against a rear wall 231 of the main housing 200, preferably in surface contact with the rear wall 231. The rear wall 231 forms the rear face 230, the rear face 230 being oriented in the opposite direction to the switching means 210. The rear wall 231 is thus interposed between the switching means 210 and the contact plate 410 when the main housing 200 is mounted on the distribution device 110, so that some of the heat generated by the switching means 210 during operation is transferred to the contact plate 410 through the rear wall.

The rear wall 231 is made from a thermally conductive and electrically insulating material. In the example illustrated, the rear wall 231 is formed by the assembly of an electrically insulating plate, made from a synthetic polymer material, and a copper plate, which provides stiffness to the assembly while promoting thermal conduction, the copper plate forming the rear face 230 and bearing against the contact plate 410 when the main housing 200 is mounted on the distribution device 110.

The main housing 200 comprises main detection means 212, which are configured to measure electrical quantities at the output terminals and to detect an electrical fault as a function of the measured values. Here, the main detection means 212 are shown by measurement loops, which are arranged here on the output lines 205. Preferably, the main detection means 212 include a differential current detection device.

The main housing 200 is configured to switch from the on configuration to the off configuration when the main detection means 212 detect a first electrical fault.

The main housing 200 comprises an electronic control unit 214, or ECU, which is configured to control the static switching means 210, in other words to switch the static switching means 210 between the on configuration and the off configuration. The electronic control unit 214 is also configured to analyse the values measured by the main detection means 212 and to determine, as a function of predefined criteria corresponding to a predetermined type of electrical fault, whether an electrical fault of the predetermined type is present. In FIG. 5, the use of predefined criteria is shown schematically by the presence of a so-called “primary” filter 222, the primary filter 222 being interposed between the main detection means 212 and the electronic control unit 214. There are several types of differential fault, which are defined in particular in IEC 60755:2017. In particular, the types of electrical fault include the electrical signal being rectified, the signal including a high-frequency component, the rating (for example 30 mA or 300 mA), etc. It will be understood that the primary filter 222 defines the criteria for the detection of electrical faults by the electronic control unit 214 of the main housing 200. Preferably, the primary filter 222 defines criteria for detecting a predetermined type of differential fault, the predetermined differential fault being selected from among the faults defined in IEC 60755:2017.

A switching time ΔC is defined as being a time interval between the instant at which the electrical fault is detected and the switch to the off configuration. The switching time ΔC thus includes the time necessary to analyse the measurements taken by the main detection means, the time necessary to send an opening order to the static switching means 210, and the switching time of the static switching means 210 once the opening order has been sent. Typically, the switching time of the static switching means 210 depends on the structure of the static switching means and is less than 1 microsecond (μs). The switching time ΔC is thus essentially linked to the operation of the electronic control unit 214. Typically, the switching time ΔC is of the order of one microsecond or approximately ten microseconds, for example between 5 μs and 500 μs.

Preferably, the main housing 200 also comprises, for each input terminal 202, a general switching device 216, which is a switching device with separable contacts, here a disconnector. The general switching device 216 is controlled by the electronic control unit 214 and makes it possible to electrically disconnect the power source from the distribution assembly 100, for example in the event that the static switching means 210 malfunction. The general switching device 216 is interposed between each input terminal 202 and the static switching means 210.

Advantageously, the distribution device 110, and by extension the distribution assembly 100, also comprises a transfer bus 150. The transfer bus 150, which is shown in isolation in FIG. 3b), is suitable for operating in order to supply energy to each outgoing box 300 in a mounted position, that is, connected to the busbars 122. Here, the transfer bus 150 is therefore an energy transfer bus, in other words a power supply bus, which is separate from the power bus 124. According to one illustrative example, the transfer bus 150 operates at a voltage of several tens of volts, for example 50 V of direct current, while the power bus 124 operates at a voltage of 400 V of alternating three-phase current. Here, the transfer bus 150 is a separate part, which is assembled with the rest of the distribution device 110.

The transfer bus 150 comprises a body 152, which is made from an electrically insulating material and has an elongate shape extending along the power bus 124. The transfer bus 150 thus extends along the main axis A110.

The transfer bus 150 defines a plurality of mounting zones 154, which are suitable for being connected to each outgoing box in a mounted position, the mounting zones 154 being distributed, preferably evenly, along the main axis A110 and each being associated with a single position along the main axis A110. The transfer bus 150 preferably comprises fifteen mounting zones, which are spaced apart from each other with a spacing of 18 mm. Other spacings are of course possible. As a variant, not shown, the mounting zones 154 are spaced apart from each other with a spacing of 9 mm.

The transfer bus 150 comprises at least two transfer lines 156, which extend along the body 152 and are configured to be electrically connected to each outgoing box 300 in a mounted position. Here, the transfer lines 156 are power supply lines, the transfer bus 150 thus being a power supply bus, which is configured to supply operating energy to each outgoing box 300, in particular to the power supply of the microcontroller 320 of each outgoing box 300. As a variant, not shown, the transfer bus 150 also serves to transfer data between each microcontroller 320 and the electronic control unit of the main housing 200. For example, the information transfer passes through the same transfer lines 156 used to transfer energy. As an alternative, not shown, the transfer bus 150 comprises specific information transfer lines, different from the transfer lines 156, which are formed on the transfer bus 150. According to another alternative, the transfer lines 156 are used for both energy transmission and information transmission.

The transfer bus 150 also comprises a connection zone 158, which is suitable for the connection of the main housing 200 in a mounted position on the distribution device 110. For example, the main housing 200 comprises an additional terminal block 250, which is configured to cooperate with the connection zone 158, so that the main housing is electrically connected to the transfer lines 156. In the preferred example illustrated, the main housing 200 draws electrical energy necessary for supplying power to the transfer bus 150 from the neutral and phases of the power source, between the static switching means 210 and the general switching device 216, the electrical energy thus supplied being available to the outgoing boxes 300 for the operation thereof.

Here, the transfer bus 150 is formed by a printed circuit board, the transfer lines 156 being conductor tracks formed on the surface of the board, while the mounting zones 154 and the connection zone 158 are leads formed in the substrate of the board.

The outgoing boxes 300 will now be described.

Each outgoing box 300 thus comprises an incoming terminal block that can be reversibly connected to the busbars 122 and comprises at least two incoming terminals 302, each incoming terminal 302 being configured to be electrically connected to a respective busbar 122. For each outgoing box 300, the incoming terminals 302, which include a neutral incoming terminal, which is configured to be electrically connected to the neutral bar, and between one and three other incoming terminals, which are each configured to be connected to a respective phase bar. Each outgoing box 300 is configured to be reversibly mounted on the power bar 114, so that each incoming terminal 302 is electrically connected to the corresponding busbar 122.

Each outgoing box 300 also comprises an outgoing terminal block, which is configured to be connected to an electrical load and comprises outgoing terminals 304, each outgoing terminal 304 respectively being associated with a respective incoming terminal 302. The outgoing terminals 304 are shown schematically in FIG 5.

In the non-limiting example illustrated, the outgoing boxes 300 have different widths, the width being measured along the main axis A110. The outgoing boxes 300 are thus split into two sub-groups, which correspond to two different widths, with narrow outgoing boxes 300 and wide outgoing boxes 300, which are approximately three times wider than the narrow outgoing boxes 300. Other widths of the outgoing boxes 300 can of course be envisaged. The width of the outgoing boxes 300 is preferably a multiple of the spacing between each mounting zone 154 of the transfer bus 150, i.e. 18 mm here. As a variant, not shown, the outgoing boxes 300 have a width equal to a multiple of 9 mm.

In the example illustrated, an outgoing box 300 configured to supply power to a single-phase electrical load advantageously has a width of 18 mm, while an outgoing box 300 configured to supply power to a three-phase electrical load has a width of three times 18 mm, i.e. 54 mm.

The narrowest outgoing boxes 300 are configured to be connected to two busbars 122, including a neutral bar and a phase bar, while the wide outgoing boxes 300 are configured to be connected to four busbars 122. The principles of the invention are applicable regardless of the number of phases to which each of the outgoing boxes 300 is connected.

Preferably, the distribution device 110 is suitable for receiving five outgoing boxes 300, which each comprise four incoming terminals, in other words five wide outgoing boxes 300. According to one example, not shown, the distribution assembly 100 comprises five outgoing boxes 300, which each comprise four incoming terminals 302. Correspondingly, the distribution device 110 is also suitable for receiving fifteen narrow outgoing boxes 300 each comprising two incoming terminals 302. The busbars each 122 comprise:
a power supply portion 126, which is configured to be connected to an associated output terminal 204 of the main housing 200 in a mounted configuration of the main housing, and
a connection portion 128, which extends from a single side of the power supply portion 126. The connection portions 128 are geometrically situated on a front side of the connection plane P124 and together define a connection zone of the power bus 124.

In FIG. 4, only the power supply portions 126 of the busbars 122 can be seen, the connection portions 128 being concealed. The connection zone is configured to receive at least one outgoing box 300, so that the outgoing box is connected to the power bus 129. The outgoing box 300 is then capable of being connected to an electrical load, so as to supply electrical power to the electrical load.

Each outgoing box 300 comprises electromechanical switching means 310, which are interposed between each incoming terminal 302 and the corresponding outgoing terminal 304. The electromechanical switching means 310 comprise separable contacts, which can be moved between a closed position, in which each incoming terminal 302 is electrically connected to the associated outgoing terminal 304, the outgoing box 300 in question being in a closed configuration, and an open position, in which an electrical current is prevented from passing between the incoming terminal 302 and the associated outgoing terminal 304, the outgoing box 300 in question being in an open configuration.

Each outgoing box 300 comprises secondary detection means 312, which are configured to measure electrical quantities at the corresponding outgoing terminals and to detect at least one predetermined type of electrical fault, that is, corresponding to predetermined detection criteria. Here, the secondary detection means 312 are schematically shown by measurement loops, which are arranged here on the wires connecting the incoming terminals 302 to the outgoing terminals 304. The schematic depiction of the secondary detection means 312 does not limit the type of electrical faults that the secondary detection means are capable of detecting. The secondary detection means 312 are thus configured to detect short-circuit type electrical faults.

For example, the secondary detection means 312 include current sensors, in particular one current sensor per phase, while the outgoing box 300 comprises a microcontroller 320, which receives the measurements from the current sensors and is capable of determining whether the current or currents measured exceed a short-circuit threshold.

Alternatively or additionally, the secondary detection means 312 include a differential current detection device. Preferably, the outgoing box 300 comprises a microcontroller 320, which is configured to evaluate the differential current measurement using a so-called “secondary” filter 322, the secondary filter 322 being stored in advance in a memory of the microcontroller 320 of the outgoing box 300 and being capable of detecting a differential fault.

The microcontroller 320 is supplied with power by means of the transfer bus 150. To this end, each outgoing box 300 comprises a transfer terminal block 350, which comprises transfer terminals (not shown), the transfer terminal block 350 being configured to be connected to the transfer bus 150 so that each transfer terminal is electrically connected to a respective transfer line 156. Here, the transfer terminal block 350 is therefore a power supply terminal block. The transfer terminals are different from the incoming terminals 302 or the outgoing terminals 304.

It will be understood that the secondary filter 322 defines the criteria for detecting the electrical faults detected by the microcontroller 320 of the outgoing box 300. Preferably, the secondary filter 322 defines criteria for detecting a predetermined type of differential fault, which is selected from among the faults defined in IEC 60755:2017.

Each microcontroller 320 is supplied with electrical energy for operation by means of the transfer bus 150, regardless of the configuration, set or tripped, of the switching mechanism, here the electromechanical switching means 310, of the outgoing box 300.

Here, each outgoing box 300 comprises an actuator 324, which is configured to move the electromechanical switching means 310 to the open position when the actuator receives a trip signal, the microcontroller 320 being configured to send the trip signal to the actuator 324 on detection of an electrical fault, in particular a short-circuit fault or a differential fault. More generally, each outgoing box 300 is configured to switch from the closed configuration to the open configuration when the secondary detection means 312, and by extension the microcontroller 320, detects an electrical fault.

The operation of the distribution assembly 100 will now be described in the event of a short-circuit fault; this operation can be transposed to other types of electrical fault, in particular differential faults. An opening time ΔO is defined as a time interval between the instant when the electrical fault is detected and the start of the movement of the separable contacts of the electromechanical switching means 310 from the closed position to the open position. In the example illustrated, the opening time includes the time taken to process the measurements by the microcontroller 320, together with the time taken by the microcontroller 320 to send the switching order to the actuator 324. Typically, the opening time ΔO is of the order of one millisecond, for example 1 ms to 9 ms.

In a minimal configuration of the distribution assembly 100, the distribution assembly comprises the distribution device 110, on which are mounted the main housing 200 and a single outgoing box 300. It is assumed that the distribution assembly 100 is connected to a power source, by means of the input terminals 202, while an electrical load is connected to the outgoing terminals 304.

In a normal operating configuration, the main housing 200 is initially in the on configuration, while the outgoing box 300 is initially in the closed configuration. The outgoing terminals 304 are thus each electrically connected to a respective output terminal 204, by means of the associated busbar 122. When an electrical fault occurs, for example due to a failure of the electrical load, the electrical fault can be detected by both the main housing 200, by means of the main detection means 212, and by the outgoing box 300, by means of the secondary detection means 312.

In other words, the electrical fault detection criteria used by the main housing 200 are identical to the electrical fault detection criteria used by the outgoing box 300 in question.

A number of types of electrical fault can be envisaged. By way of illustration, in the event of a short-circuit, a short-circuit current can reach several times, for example five times, the value of a rated operating current. Other examples of electrical faults include overcurrents, differential current faults, etc. Compared with short-circuit faults, the electrical currents involved in the event of overcurrents or differential faults are much lower, for example less than 1.2 times the value of the rated operating current.

In the example illustrated, the detection criteria are defined by the detection filters, i.e. here the primary filter 222 for the main housing 200, and the secondary filter 322 for the outgoing box 300. In the event of a short-circuit fault, it is assumed that the primary filter 222 and the secondary filter 322 operationally define the same detection criteria, in other words, that the primary filter 222 and the secondary filter 322 are operationally identical to each other, so that the main housing 200 and the outgoing box 300 are configured to detect electrical faults according to the same criteria.

The distribution assembly 100 is configured so that, when an electrical fault that matches the criteria of the first filter 222 and of the second filter 322 occurs:
the outgoing box 300 detects the electrical fault by means of the secondary detection means 312, then the microcontroller 320 of the outgoing box commands the electromechanical switching means 310 to switch to the open position,
while the main housing 200 detects the same electrical fault by means of the main detection means 212, then the electronic control unit 214 of the main housing 200 commands the switching means 210 to switch to the off configuration.

Given the proximity of the main housing 200 to the outgoing box 300, the detection of the same electrical fault by the main housing 200 and by the outgoing box 300 is considered to be simultaneous.

The distribution assembly 100 is configured so that the main housing 200 switches to the off configuration before the first box switches from the closed configuration to the open configuration. In other words, the switching time ΔC is shorter than the opening time ΔO, so that when the separable contacts of the electromechanical switching means 310 start to move from the closed position to the open position, no current is circulating in the power bus 114. The separable contacts of the electromechanical switching means 310 open without any electrical arc being generated, which makes it possible to reduce the wear of the separable contacts and contributes to the durability of the outgoing boxes 300.

Once the outgoing box 300 is in the open configuration, the main housing 200 is configured to switch from the off configuration to the on configuration at the end of a predetermined waiting time ΔW, the waiting time being longer than the opening time.

A situation in which the distribution assembly comprises two or more outgoing boxes 300 is considered, the two outgoing boxes 300 including a first box and a second box, which are jointly connected to the busbars 122. In other words, the two outgoing boxes 300 are mounted on the same distribution device 110. In normal operation of the distribution assembly 100, the main housing 200 is initially in the on configuration, while the first box 300 and the second box 300 are each initially in the closed configuration. It is assumed that the first box 300 and the second box 300 are each connected to a respective electrical load.

When an electrical fault occurs at the outgoing terminals 304 of the first box 300, for example following a failure of the electrical load connected to the first box 300, the first outgoing box 300 detects this electrical fault by means of the secondary detection means 312 of the first box 300 and, simultaneously, the main housing 200 also detects this electrical fault by means of the main detection means 212. As above, the main housing 200 switches to the off configuration before the first box 300 switches from the closed configuration to the open configuration, while the second box 300 remains in the closed configuration.

Next, the main housing 200 switches from the off configuration to the on configuration at the end of the waiting time ΔW, the second box 300 remaining in the closed configuration. The waiting time ΔW is sufficiently short so that the interruption to the power supply experienced by the electrical load associated with the second box 300 has no negative impact. In practice, the waiting time ΔW is less than 20 ms, preferably less than 15 ms, more preferably less than 10 ms.

In the example illustrated, each outgoing box 300 comprises a microcontroller 320, which analyses the measurements of the secondary detection means 312 and determines whether an electrical fault is present, in particular a differential fault. This requires that the microcontroller be supplied with power by an electrical energy source, here by means of the transfer bus 150. The principles of the invention can be transferred to a situation in which the outgoing boxes 300 do not comprise a microcontroller, the actuator 324 being for example directly supplied with power by the current differential measured by the secondary detection means 312.

The aforementioned embodiments and variants can be combined with each other to generate new embodiments of the invention.

1. A distribution assembly, configured to distribute electrical energy from a power source to at least one electrical load, the power source comprising a neutral and at least one phase, wherein:
the distribution assembly comprises a power bus, which comprises a plurality of busbars:
which include at least one phase bar, each phase bar being associated respectively with a phase of the power source,
which extend parallel to each other along a main axis of the distribution assembly and are aligned along a height axis that is orthogonal to the main axis,
the busbars each each comprise:
a power supply portion, which is configured to be connected to an output terminal of a main housing in a mounted configuration of the main housing,
a connection portion, which extends from a single side of the power supply portion, the connection portions being geometrically situated on a front side of a connection plane parallel to the main axis and to the height axis and together defining a connection zone of the power bus, the connection zone being configured to receive at least one outgoing box so that outgoing box is connected to the power bus, each outgoing box being capable of being connected to a respective electrical load, so as to supply electrical power to the electrical load,
the distribution assembly comprises a cooling device, which includes:
a contact plate, which has a contact face that extends parallel to the connection plane, the contact face being configured to cooperate, in particular through complementary shapes, with a rear face of the main housing in a mounted configuration, so as to promote thermal transfer between the contact plate and the main housing,
a radiator that extends along the connection zone, on a rear side of the connection plane,
at least one heat pipe, which connects the contact plate to the radiator and is configured to transfer some of the heat collected by the contact plate to the radiator, the radiator being configured to dissipate the heat transferred by each heat pipe into the air.

2. The distribution assembly according to claim 1, wherein:
the distribution assembly includes the main housing, the main housing being mounted on the rest of the distribution assembly and comprising:
input terminals, which are configured to be connected to each phase of the power source,
output terminals, which are connected to the busbars, each output terminal being associated with a respective busbar and a respective input terminal,
the rear face, which cooperates, in particular through complementary shapes, with the contact face.

3. Distribution The distribution assembly according to claim 2, wherein:
the main housing comprises switching means, in particular static, which can be switched between an on configuration, in which each input terminal is electrically connected to the associated output terminal, the main housing being in an on configuration, and an off configuration, in which an electrical current is prevented from passing between the input terminal and the associated output terminal, the main housing being in an off configuration,
the main housing comprises a rear wall, which is made from a thermally conductive and electrically insulating material and comprises the rear face, the rear wall being interposed between the switching means and the contact plate, so that some of the heat generated by the switching means during operation is transferred to the contact plate through the rear wall.

4. The distribution assembly according to claim 1, wherein the at least one heat pipe is a two-phase heat pipe.

5. The distribution assembly according to claim 4, wherein:
the at least one heat pipe is a capillary two-phase heat pipe,
when the distribution assembly is in a normal operating configuration, the main axis is horizontal.

6. The distribution assembly according to claim 1, wherein:
the distribution assembly comprises an insulating wall, which is made from an electrically insulating material and is interposed between the power bus and the radiator, the insulating wall being open towards the front of the contact plate,
the output terminals of the main housing are connecting clips, which are each suitable for connection to a respective busbar, in a connection movement oriented towards the rear of the distribution assembly so that, during the movement to connect the output terminals to the busbars, the rear face of the main housing bears against the contact face.

7. The distribution assembly according to claim 1, wherein:
the distribution assembly comprises a rear portion, which forms a cavity for receiving the cooling device, the rear portion being made from an electrically insulating material,
the rear portion is perforated, so as to promote the cooling of the cooling device by convection.

8. An electrical panel, comprising:
a case, defining an enclosure and having a base,
the distribution assembly according to claim 1,
wherein the distribution assembly is fastened to the base of the case, the main axis being parallel to the base of the case.

9. The electrical panel according to claim 8, wherein the main axis is horizontal.

10. The distribution assembly according to claim 1, further comprising wherein the plurality of busbars comprises a neutral bar, the neutral bar being associated with the neutral of the power source.

11. The distribution assembly according to claim 2, further comprising wherein the input terminals are further configured to be connected to the neutral of the power source.
